(19) United States
(12) Patent Application Publication
(10) Pub. No.: US 2007/0152341 A1
(43) Pub. Date: Jul. 5, 2007

(54) Copper wiring protected by capping metal layer and method for forming for the same

(75) Inventors: Jong-Taek Hwang, Seoul (KR); Han-Choon Lee, Seoul (KR)

Correspondence Address: MAYER, BROWN, ROWE & MAW LLP, 1909 K STREET, N.W., WASHINGTON, DC, 20006, US

(73) Assignee: Dongbu Electronics Co., Ltd.

(21) Appl. No.: 11/641,036

(22) Filed: Dec. 19, 2006

(30) Foreign Application Priority Data
Dec. 29, 2005 (KR) 10-2005-0134133

(51) Int. Cl. H01L 21/4763

(52) U.S. Cl. 257/762; 438/687; 438/637; 438/627

(57) ABSTRACT

A method for forming a copper metal wiring by using a damascene process, which includes the steps of: forming a damascene pattern on an interlayer insulating film on a semiconductor substrate; forming a barrier metal layer inside the damascene pattern; forming a copper layer in the damascene pattern; and forming a capping metal layer on the copper layer. Particularly, a top surface of the copper layer is buried in the damascene pattern to be lower than a top surface of the interlayer insulating film.

### FIELD OF THE INVENTION

The present invention relates to a technique for manufacturing a semiconductor device; and, more particularly, to a technique for forming a metal wiring in the semiconductor device.

### BACKGROUND OF THE INVENTION

A semiconductor manufacturing process is largely divided into a FEOL (front end of the line) for forming transistors on a silicon substrate and a BEOL (back end of the line) for forming a wiring thereon. Here, the BEOL is a process for forming paths for a power supply and a signal transmission by interconnecting the individual transistors, thus forming an integrated circuit.

Copper (Cu) having a high EM (electro-migration) resistance is widely employed in the BEOL process. However, copper is difficult to etch and easily oxidized during the process making patterning copper difficult with a general photolithographic technique. Thus, a dual damascene technique has been developed to form a copper wiring. The dual damascene process involves: forming a damascene pattern as a via and a trench on an interlayer insulating film formed on a substrate; burying copper in the damascene pattern by employing an ECP (electro-chemical plating) method; and then planarizing a top surface of a substrate structure through a CMP (chemical mechanical polishing) process.

FIG. 1 shows a lower metal wiring 18a and an upper metal wiring 18b formed successively through a conventional dual damascene process. The lower metal wiring 18a is formed in via 12a and trench 14a in an interlayer insulating film 20a, and the upper metal wiring 18b is formed in via 12b and trench 14b in an interlayer insulating film 20b. Further, barrier metal layers 16a and 16b formed of, e.g., a tantalum (Ta) film and/or tantalum nitride (TaN) film, are respectively interposed between interlayer insulating films 20a and the metal wiring 18a and between interlayer insulating films 20b and the metal wiring 18b. Barrier insulating film 10 formed of, e.g., silicon nitride film, may also be interposed between the interlayer insulating films 20a and 20b.

In general, electron transfer of a metal material occurs on the surface of the metal. Accordingly, if a semiconductor device is operated, electrons are transferred along the surface of metal wirings 18a and 18b near the upper portions of trenches 14a and 14b. However, in an area A where the metal wiring 18a is in contact with the barrier insulating film 10, the flow of the electrons cannot be made smoothly, because the barrier insulating materials generally have a high electric resistance, which can impede the flow of the electrons. Accordingly, if the device is operated for a long period of time in this condition, reliability of the metal wirings can deteriorate.

### SUMMARY OF THE INVENTION

In accordance with one embodiment of the present invention, there is provided a method for forming a copper metal wiring by using a damascene process, comprising the steps of: forming a damascene pattern on an interlayer insulating film on a semiconductor substrate; forming a barrier metal layer inside the damascene pattern; forming a copper layer in the damascene pattern; and forming a capping metal layer on the copper layer.

In accordance with another embodiment of the present invention, there is provided a semiconductor device provided with a copper metal wiring formed by employing a damascene process, comprising a capping metal layer which is locally formed on a top portion of the copper metal wiring.

It is, therefore, an object of the present invention to provide a method for improving an electric conductivity of a copper metallization wiring layer by forming a capping metal layer for protecting a top surface of the copper metallization wiring.

### BRIEF DESCRIPTION OF THE DRAWINGS

The above and other objects and features of the present invention will become apparent from the following description of preferred embodiments, given in conjunction with the accompanying drawings, in which:

FIG. 1 is a cross sectional view of a conventional semiconductor device having an upper and a lower copper metal wiring formed therein;

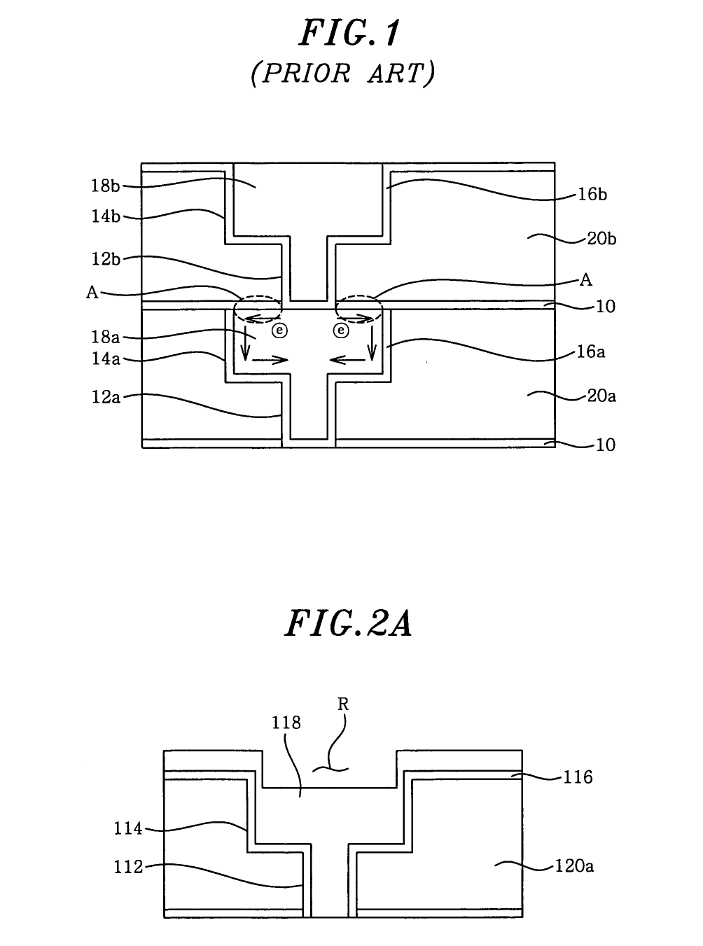

FIGS. 2A to 2C provide cross sectional views of a copper metal wiring in accordance with one embodiment of the present invention;

FIG. 3 presents a cross sectional view of a semiconductor device having two copper metal wirings formed therein in accordance with one embodiment of the present invention.

### DETAILED DESCRIPTION OF THE PREFERRED EMBODIMENTS

Hereinafter, a copper metal wiring and a method for the formation thereof will be described in detail with reference to the accompanying drawings. Throughout the drawings, like parts or components are designated by the same reference numerals, with no duplicate description given in that regard.

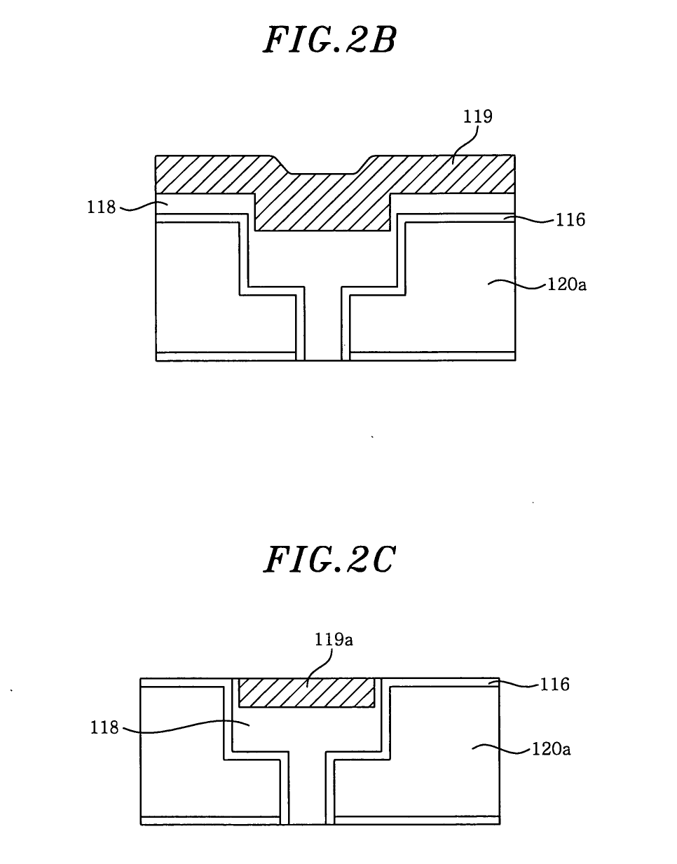

FIG. 2A shows a copper layer 118 formed in a damascene pattern having a via 112 and a trench 114 provided at an interlayer insulating film 120a, wherein the copper layer 118 is formed by employing an ECP method. A process for forming the damascene pattern in the interlayer insulating film 120a and a process for forming a copper seed layer (not shown) and a barrier metal layer 116, which is formed of a tantalum (Ta) film or a dual film of Ta/tantalum nitride (TaN), are similar to conventional methods, so description thereof will be omitted here.

In a general damascene process where patterns are formed on a substrate, a pattern of a smaller width will be buried faster than a pattern of a larger width. Traditionally, an additional plating step is carried out to completely fill any gap(s) within the larger-width pattern. Additional plating processes are usually referred to as bulk plating, which allows a thick coating layer to be formed that can fill in any gaps.

However, in this preferred embodiment, the bulk plating is not performed. Instead, a copper plating is conducted until a recess of a preset depth is formed at a top portion of the damascene pattern, without sealing the damascene pattern completely. In other words, a recess R can be formed on the copper layer 118 due to a part of the damascene pattern yet to be buried. Accordingly, as shown in FIG. 2A, the top surface of the copper layer 118 buried in the damascene pattern can be formed to be lower than at least the top surface of the interlayer insulating film 120a.

Thereafter, as illustrated in FIG. 2B, a capping metal layer 119 is formed on the entire surface of the copper layer. The capping metal layer 119 can be formed of Ta, TaN, cobalt (Co), CoSi₂, CoWP, or the like. Further, the capping metal layer 119 can be formed by a physical vapor deposition, a chemical vapor deposition, an atomic layer deposition, or the like.

Subsequently, as shown in FIG. 2C, a resulting substrate structure is planarized by employing a chemical-mechanical polishing method. Through this planarization process, a part of the capping metal layer 119 deposited on the interlayer insulating film 120a is removed. As a result, a copper metal wiring 118 is formed in the damascene pattern, and the capping metal layer 119a remains on the top surface of the copper metal wiring 118.

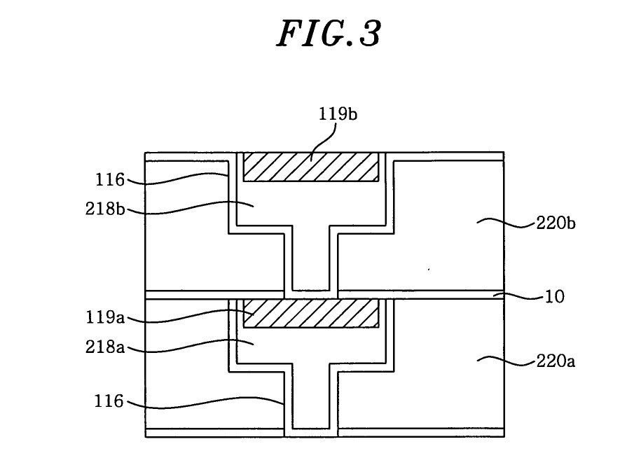

FIG. 3 shows two metal wirings 218a and 218b formed successively by the above-described method. Metal wirings 218a and 218b are respectively embedded in interlayer insulating films 220a and 220b. Further, because capping metal layers 119a and 119b are formed on the top surfaces of metal wirings 218a and 218b on which no barrier layer 116 exists, the top surfaces of the metal wirings can be prevented from contacting an insulating film having a high electrical resistance directly. Accordingly, the flow of electrons is not hampered by the insulating film, e.g., barrier insulating film 10, so that performance of the metal wirings can be improved.

In accordance with the present invention, a top surface of a metal wiring layer is protected by a capping metal layer, thus being prevented from contacting an insulating film directly. Therefore, a smooth flow of electrons in the metal wiring layer is allowed.

While the invention has been shown and described with respect to the preferred embodiments, it will be understood by those skilled in the art that various changes and modifications may be made without departing from the spirit and scope of the invention as defined in the following claims.

What is claimed is:

1. A method for forming a copper metal wiring by using a damascene process, comprising the steps of:
(a) forming a damascene pattern on an interlayer insulating film on a semiconductor substrate;
(b) forming a barrier metal layer inside the damascene pattern;
(c) forming a copper layer in the damascene pattern; and
(d) forming a capping metal layer on the copper layer.

2. The method of claim 1, wherein in the step (c), a top surface of the copper layer is buried in the damascene pattern to be lower than a top surface of the interlayer insulating film.

3. The method of claim 1, wherein after the capping metal layer is formed in the step (d), a capping metal layer's portion deposited on the interlayer insulating film is removed by planarizing an entire surface of a substrate structure having the capping metal layer.

4. The method of claim 1, wherein the capping metal layer is locally formed on a top portion of the copper layer buried in the damascene pattern.

5. The method of claim 1, wherein the capping metal layer is formed of a material selected from the group consisting of Ta, TaN, Co, CoSi₂, or CoWP.

6. A semiconductor device provided with a copper metal wiring formed by employing a damascene process, comprising a capping metal layer which is locally formed on a top portion of the copper metal wiring.

7. The semiconductor device of claim 6, wherein the capping metal layer is formed of at least one of Ta, TaN, Co, CoSi₂, and CoWP.

8. The semiconductor device of claim 6, wherein the capping metal layer serves to protect the top portion of the copper metal wiring.
